(19) United States
(12) Patent Application Publication
(10) Pub. No.: US 2013/0299947 A1
(43) Pub. Date: Nov. 14, 2013

(54) PASSIVATED TEST STRUCTURES TO ENABLE SAW SINGULATION OF WAFER

(71) Applicant: Trent S. Uehling, New Braunfels, TX (US)

(72) Inventor: Trent S. Uehling, New Braunfels, TX (US)

(73) Assignee: FREESCALE SEMICONDUCTOR, INC., Austin, TX (US)

(21) Appl. No.: 13/470,448

(22) Filed: May 14, 2012

(51) Int. Cl. H01L 23/544; H01L 21/78

(52) U.S. Cl. 257/620; 438/462; 257/E23.179; 257/E21.599

(57) ABSTRACT

A wafer having a die area and a scribe street is formed. The die area comprises die circuitry and a plurality of bond pads, and the scribe street comprises a test structure. Circuitry of the test structure is probed, and then a passivation layer overlying the surface of the wafer is formed, the passivation layer overlying the plurality of bond pads and overlying the test structure. Openings in the regions of the passivation layer overlying the plurality of bond pads are then formed to expose the plurality of bond pads while retaining the regions of the passivation layer overlying the test structure until singulation of the wafer. Pad metallizations are formed at the plurality of bond pads via the openings in the regions of the passivation layer and the wafer is singulated. The resulting dies may be packaged and the resulting IC packages may be implemented in electronic devices.

### FIELD OF THE DISCLOSURE

The present disclosure relates generally to fabricating semiconductor devices and more particularly to fabricating, testing, and singulating a semiconductor wafer.

### BACKGROUND

In a typical semiconductor manufacturing process, test structures located in the scribe streets that separate the die areas of a semiconductor wafer typically are metalized with a relatively hard metal as part of the over pad metallization (OPM) process for the bond pads of the die areas. The over pad metal formed through this process typically is relatively hard and thus the metalized test structures in the scribe streets are difficult to saw cut during singulation without causing chipping, cracking, and delamination of the metal and dielectric layers, which can propagate to the die areas and cause immediate or latent electrical failures of the resulting semiconductor devices. Conventional techniques for mitigating the problems introduced by sawing through the relatively hard metals formed on the test structures in the scribe streets, such as by reducing the cut speed or changing saw blades more frequently.

### BRIEF DESCRIPTION OF THE DRAWINGS

The present disclosure may be better understood, and its numerous features and advantages made apparent to those skilled in the art by referencing the accompanying drawings.

FIG. 1 is a diagram illustrating a top view of a semiconductor wafer employing passivated test structures in a scribe grid in accordance with at least one embodiment of the present disclosure.

FIGS. 2 and 3 illustrate a flow diagram and corresponding sequence of cross-sectional views of a portion of the semiconductor wafer that together illustrate a method of fabricating a semiconductor wafer in accordance with at least one embodiment of the present disclosure.

### DETAILED DESCRIPTION

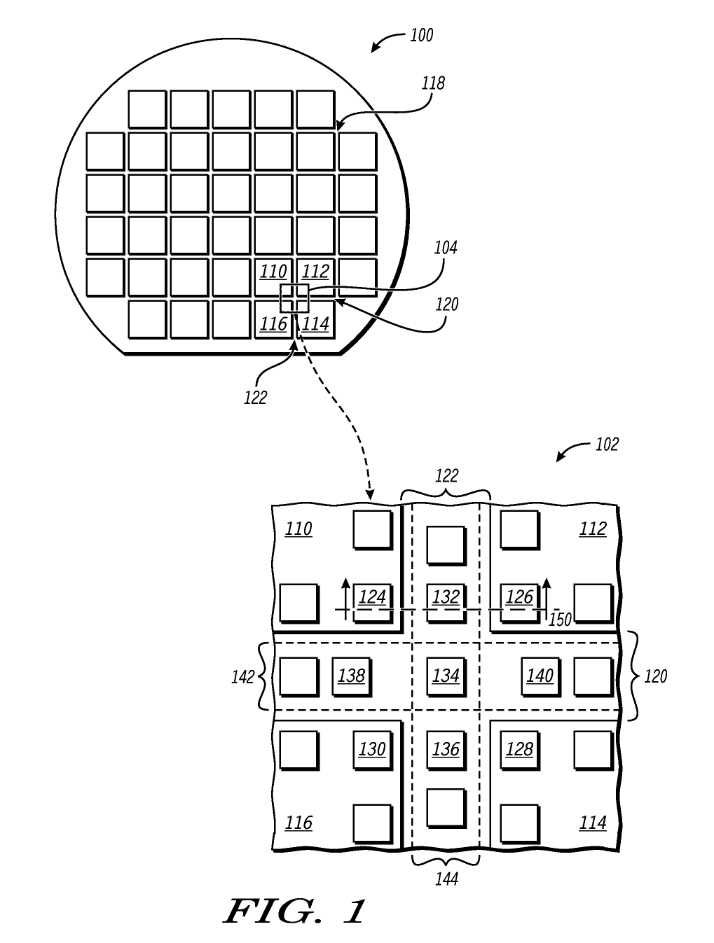

FIGS. 1-3 illustrate example techniques for fabricating semiconductor devices from a semiconductor wafer. The semiconductor wafer is formed with a plurality of die areas separated by a scribe grid comprising a plurality of scribe streets, which serve as the dicing lines for a mechanical or other saw process used to separate the die areas into individual dies (“dies” being used herein as the plural of “die”). One or more test structures are formed in the scribe streets so as to facilitate wafer-class testing of test structures in the scribe streets to determine potential yield of the wafer and to collect parametric data pertaining to the wafer fabrication process. The test structures typically are formed of relatively soft metals, such as aluminum (Al), copper (Cu), or alloys thereof. Wafer-class testing of the wafer is performed by stimulating the test circuitry of test structures via metal probe tips in contact with the test structure contact pads located in the scribe grid. In at least one embodiment, scribe grid pads are formed in the scribe streets to provide contact points for the metal probe tips. After the wafer-class testing is complete, a blanked passivation layer is formed overlying the active surface of the semiconductor wafer. This passivation layer is then opened at regions overlying the bond pads of the die areas so as to expose at least a portion of each of the bond pads while the regions of the passivation layer overlying the scribe grid pads and other test structures of the scribe streets are retained, and thus the test structures remain passivated. A maskless over pad metallization (OPM) process, such as an electroless nickel (Ni) process, then is performed to form pad metallizations (e.g., metal bumps) on the bond pads of the die areas. However, because the test structures of the scribe streets remained passivated, the maskless OPM process does not form over pad metal at the scribe grid pads of the scribe streets. The dies of the wafer are then singulated using a mechanical saw process. Because relatively-hard metal is absent from the scribe grid due to the passivated test structures, the mechanical saw process is less prone to introduce chipping, cracking, and delamination when sawing through the test structures in the scribe streets of the wafer.

FIG. 1 illustrates a top view of a semiconductor wafer 100 and a top layout view 102 of a portion 104 thereof in accordance with at least one embodiment of the present disclosure. The semiconductor wafer 100 (hereinafter, “wafer 100”) can comprise, for example, a single crystal silicon wafer over which semiconductor integrated circuit devices or microelectromechanical systems (MEMS) are formed, or instead may include a composite wafer of an insulating substrate, such as an epitaxial wafer, a silicon-on-insulator (SOI) wafer, or a liquid crystal display (LCD) glass substrate and a semiconductor layer, and the like. The wafer 100 comprises a plurality of die areas, such as die areas 110, 112, 114, and 116 (collectively, “die areas 110-116”), comprising semiconductive, conductive, or dielectric material formed thereon. The die areas are separated from one another by a scribe grid 118 comprising a plurality of perpendicular scribe streets, such as horizontal scribe street 120 and vertical scribe street 122, with “horizontal” and “vertical” being relative to the illustrated orientation of FIG. 1.

The die areas represent active/functional areas of the wafer 100 in which die circuitry is formed for inclusion in corresponding semiconductor dies after singulation of the wafer. The die areas have formed therein bond pads for connecting to power, ground and input/output (I/O) pads or leads of a corresponding package substrate or leadframe. Moreover, various test structures, including interconnect structures, process control (PC) structures, and scribe grid pads, are formed in various scribe streets of the scribe grid 118 to facilitate wafer-class probe tests of the test structures. To illustrate, view 102 depicts corner portions of die areas 110-116 separated by, and adjacent to, the scribe streets 120 and 122. The die areas 110-116 each include a plurality of bond pads, such as bond pads 124, 126, 128, and 130 for die areas 110, 112, 114, and 116, respectively. Further, various test structures, such as scribe grid pads 132, 134, 136, 138, and 140, interconnect structures (not shown), process control structures (not shown) and photo alignment keys (not shown), are formed in the scribe streets 120 and 122 for use in testing to determine potential yield of the wafer and to collect parametric data pertaining to the wafer fabrication process.

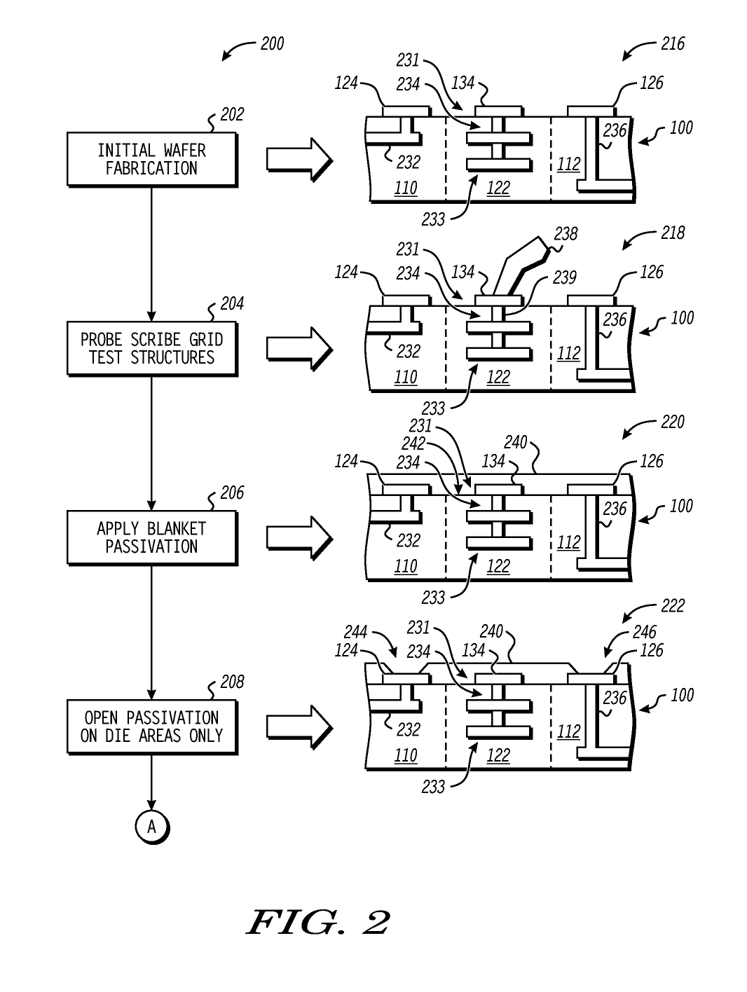

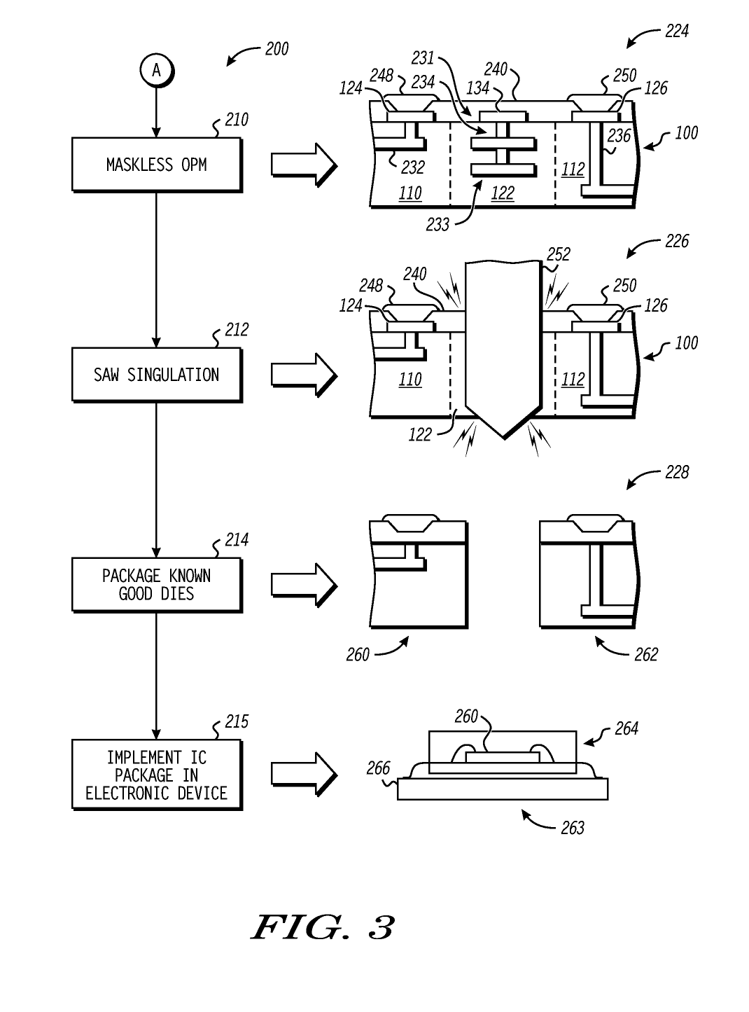

During a saw singulation process, the various die areas are separated by sawing within the scribe streets of the scribe grid. The material removed during the sawing process is contained within saw kerf regions, such as saw kerf regions 142 and 144 for scribe streets 120 and 122, respectively. The test structures of the scribe streets often are positioned in these saw kerf regions, and thus can impact the singulation process. As described in greater detail below with reference to FIGS. 2 and 3, in at least one embodiment, wafer-level probe testing is performed by probing the test structures of the scribe streets and the scribe streets are then subjected to blanket passivation after probe testing. The passivation material is substantially retained in the scribe streets during the process of opening regions of the passivation layer expose at least portions of the bond pads of the die areas so that no over pad metallization occurs on the test structures during a subsequent maskless over pad metallization process. Consequently, the mechanical saw singulation process is less prone to the chipping, cracking, and delamination frequently found in conventional wafer processes that plate the test structures with relatively hard materials in conjunction with the metallization of the bond pads of the die areas. As such, the wafer 100 can be more reliably singulated with lower yield loss compared to conventional wafer processing techniques.

FIGS. 2 and 3 illustrate an example method 200 of fabricating, probing testing, and singulating a semiconductor wafer in accordance with at least one embodiment of the present disclosure. The method 200 is described below in the example context of the semiconductor device 100 of FIG. 1. FIGS. 2 and 3 also illustrate corresponding cross-section views of the region 104 of the wafer 100 at section 150 (FIG. 1) for each corresponding sub-process of method 200.

At block 202, a series of semiconductor fabrication processes are performed to substantially complete fabrication of the wafer 100, including the formation of integrated circuit devices in the die areas of the semiconductor wafer and test structures in the scribe grid 118 through a last metal layer. Formation of the last metal layer includes the formation of the bond pads and scribe grid pads and other test structures at the surface of the wafer 100. The bond pads, scribe grid pads, and test structures may be formed from any of a variety of metals, metal alloys, or layered combinations thereof. To illustrate, the scribe grid pads and bond pads may comprise at least one of aluminum (Al) and copper (Cu) as a principal component, such as a layer of aluminum or aluminum alloy overlying a layer of copper or copper alloy. The bond pads and scribe grid pads are electrically connected to various die circuits and test circuitry, respectively, through one or more conductive interconnect structures.

As illustrated by section view 216 of the wafer 100 at this point in the fabrication process, the wafer 100 has formed at a top surface a top metal layer comprising the bond pads 124 and 126 formed in the die areas 110 and 112, respectively, and test structure 231 formed in the scribe street 122 between the die areas 110 and 112, the test structure 231 comprising the scribe grid pad 134, test circuitry 233 and an interconnect structure 234. In the depicted example, the bond pad 124 is connected to die circuitry (not shown) of the die area 110 via an interconnect structure 232, the scribe grid pad 134 is connected to the test circuitry 233 via the interconnect structure 234 and the bond pad 126 is connected to integrated circuits of the die area 112 via an interconnect structure 236.

At block 204, the wafer 100 is subjected to one or more wafer-class probe scribe grid tests to determine potential yield of the wafer 100 and to collect parametric data pertaining to the wafer fabrication process. As part of this process, metal probe tips of a probe tester are placed in contact with the test structures located in the scribe grid 118 and the corresponding test structure circuitry is stimulated via the metal probe tips. In one embodiment, the metal probe tips are placed in electrical contact with the test structure circuitry via physical contact with the scribe grid pads of the scribe grid 118. To illustrate, section view 218 depicts a metal probe tip 238 placed in physical and electrical contact with scribe grid pad 134 so as to either excite the test circuitry 233 or to receive signaling from the test circuitry 233 in response to excitation of the test circuitry 233 by another probe tip via another scribe grid pad. In an alternative embodiment, formation of a scribe grid pad is omitted for some or all of the test structures located in the scribe grid 118, and the probe tests are conducted by placing metal probe tips in physical contact with the interconnect structures (e.g., in physical contact with a via 239 of the interconnect structure 234 of the test structure 231). Information regarding the potential yield of the wafer 100 and parametric data pertaining to the wafer fabrication process is obtained by the probe tester.

At block 206, a blanket passivation layer 240 overlying the scribe grid 118, die areas at a top surface 242, bond pads 124 and 126, and scribe grid pad 134 of the wafer 100 is formed by depositing one or more dielectric materials, such as, for example, silicon nitride, silicon dioxide, silicon oxynitride, a polyimide, spin-on glass (SOG), borosilicate glass, tetra-ethoxy-silane, fluorinated tetra-ethoxy-silane, or combinations or layers thereof. In one embodiment, the passivation layer 240 has a thickness of about 200 to 1200 nanometers. In another embodiment, the passivation layer 240 has a thickness of about 1 to 8 micrometers. As illustrated in section view 220, in one embodiment, the blanket passivation layer 240 overlies and is in contact with the test structures and their scribe grid pads located in the scribe grid 118 (such as test structure 231 and scribe grid pad 134), and overlies some or all of the bond pads of the die areas of the wafer 100 (such as bond pads 124 and 126).

At block 208, passivation openings (also called “bond pad openings”) are formed in regions of the passivation layer 240 overlying the active die areas so as to expose at least a portion of each of the bond pads, while retaining the passivation layer 240 substantially intact in the regions overlying the scribe streets, and thus retaining the passivation layer 240 substantially intact in the regions overlying the scribe grid pads and other test structures of the scribe grid. The passivation openings may be formed using any of a variety of techniques, such as a photo etch process to remove the passivation material overlying the bond pads of the die area using a mask that prevents etching of the scribe grid 118. As illustrated by section view 222, passivation openings 244 and 246 are formed in the passivation layer 240, wherein passivation opening 244 is located above, and exposing, at least a portion of the bond pad 124, and passivation opening 246 is located above, and exposing, at least a portion of the bond pad 126. As also illustrated by section view 222, the passivation layer 240 is retained in the regions of the scribe street 122 so as to substantially or completely overly and contact the scribe grid pad 134 and the other scribe grid pads located in the scribe grid 118.

At block 210, an over pad metallization (OPM) process is performed to form pad metallizations (e.g., metal bumps) on the bond pads of the die areas of the wafer 100 via the passivation openings of the passivation layer 240. In at least one embodiment, a maskless over pad metallization process is used to form the pad metallizations such that the pad metallizations are formed in passivation openings and are prevented from forming in locations the passivation material is present. The maskless over pad metallization layer can include, for example, an electroless nickel plating process, such as electroless nickel/immersion gold (ENIG), electroless nickel/electroless palladium (ENEP), and electroless nickel/electroless palladium/immersion gold (ENEPIG). The pad metallizations can comprise any of a variety of metals in various combinations and layers, such as, for example, nickel (Ni), palladium (Pd), gold (Au), or alloys thereof as principal components, as well as multiple layers of these metals or alloys. To illustrate, the pad metallizations can include a bottom layer of Ni in contact with the bond pads and formed via, for example, an electroless Ni plating process, a Pd layer overlying the Ni layer and formed via, for example, an electroless Pd plating process, and an Au layer overlying the Pd layer and formed via, for example, an electroless Au plating process, an immersion plating process, or an electroplating process. In one embodiment, the total thickness of the over pad metallizations can range from 500 nanometers to 5 micrometers. Other thicknesses can be used in other embodiments.

As illustrated by section view 224 of wafer 100, the OPM process results in the formation of pad metallization 248 in the passivation opening 244 and pad metallization 250 in the passivation opening 246, whereby the pad metallization 248 is in physical and electrical contact with the bond pad 124 and the pad metallization 250 is in physical and electrical contact with the bond pad 126. Moreover, because the passivation layer 240 was retained over the scribe grid 118, pad metallizations are prevented from forming on the scribe grid pad 134 and the other scribe grid pads located in the scribe grid 118.

At block 212, the wafer 100 is singulated using a mechanical saw process in which one or more saw blades, such as saw blade 252, traverse the scribe streets of the scribe grid 118 to separate the die areas into individual dies. As illustrated by section view 226, the saw blade 252 is drawn through the scribe street 122 (including through the scribe grid pad 134 and the underlying interconnect structure 234) so as to separate the die area 110 and the die area 112. Because pad metallizations were prevented from being formed in the scribe streets due to the overlying blanket passivation layer 240 and because the scribe grid pads and other test structures located in the scribe grid 118 are composed of relatively soft metals such as Al and Cu, the saw blade 252 is able to saw through the scribe grid pads and test structures with relative ease and with relatively less chipping, cracking, and delamination compared to a semiconductor wafer in which pad metallizations including Ni and other relatively hard metals are permitted to be formed in the scribe streets.

At block 214, the singulated dies resulting from the singulation process (such as dies 260 and 262 of section view 228) are sorted into known good dies and bad dies. The known-good dies are then wire bonded or chip bonded to a I/O substrate or lead frame, packaged, and subjected to final testing, ultimately resulting in the production of a functional IC package. At block 215, the functional IC package is implemented in an electronic device. The electronic device can include any of a variety of electronic devices, such as an electronic control system of an automobile or other vehicle, a portable electronic device such as a cellular phone, tablet computer, notebook computer, a desktop computer, a server, and the like. To illustrate, FIG. 3 depicts an electronic device 263 in which an IC package 264 is implemented. The IC package 264 includes one or more dies, such as the die 260, wirebonded to a leadless or lead-based frame. The IC package 264 can include any of a variety of package structures, such as a ball grid array (BGA), flip-chip, redistributed chip packaging (RCP), and the like.

A method includes probing circuitry of a test structure of a wafer having a first die area and a scribe street at a surface of the wafer, the first die area comprising die circuitry and a plurality of bond pads, and the scribe street comprising the test structure. The method further includes forming a passivation layer overlying the surface of the wafer after probing the circuitry, the passivation layer overlying the plurality of bond pads and overlying the test structure. The method additionally includes forming openings in regions of the passivation layer overlying the plurality of bond pads to expose the plurality of bond pads while retaining regions of the passivation layer overlying the test structure until singulation of the wafer. The method further can include forming pad metallizations at the plurality of bond pads via the openings in the regions of the passivation layer prior to singulation of the wafer without forming a pad metallization at the test structure and singulating the wafer into a plurality of dies. Forming the pad metallizations can include metalizing the plurality of bond pads using a maskless over pad metallization (OPM) process. Aluminum or copper can be a principal component of the plurality of bond pads, nickel can be a principal component of the pad metallizations, and the maskless OPM process can include an electroless nickel plating process.

In accordance with one aspect, the test structure comprises a scribe grid pad located in the scribe street, and wherein probing the circuitry comprises contacting the scribe grid pad with a metal probe tip. The passivation layer can overlie and contact the scribe grid pad. Alternatively, the test structure can comprise a conductive interconnect structure located in the scribe street, and probing the circuitry can comprise contacting the conductive interconnect structure with a metal probe tip.

In another embodiment, a method includes forming a passivation layer overlying a surface of a wafer having a plurality of die areas separated by a scribe grid at the surface of the wafer, each die area comprising die circuitry and a plurality of bond pads, and the scribe grid comprising a plurality of scribe grid pads, each scribe grid pad electrically coupled to corresponding test structure circuitry, the passivation layer overlying the bond pads of the plurality of die areas and overlying the plurality of scribe grid pads. The method also includes forming passivation openings in regions of the passivation layer that overly the plurality of die areas to expose the bond pads of the plurality of die areas while retaining regions of the passivation layer overlying the scribe grid pads, and metalizing the bond pads via the passivation openings without metalizing the scribe grid pads. The method additionally includes singulating the plurality of die areas via the scribe grid. Singulating the plurality of die areas can comprise traversing the scribe grid with a mechanical saw. Metalizing the bond pads can comprise forming a pad metallization in each of the passivation openings using a maskless over pad metallization (OPM) process.

In accordance with another aspect, a semiconductor wafer includes a first die area comprising a first plurality of bond pads, the first plurality of bond pads coupled to die circuitry of the first die area, and a scribe street adjacent to the first die area, the scribe street comprising a test structure. The wafer further includes a passivation layer overlying the first die area and the scribe street, the passivation layer overlying the test structure, and first pad metallizations in openings (244) in the passivation layer overlying the first plurality of bond pads, each first pad metallization contacting at least a portion of a corresponding bond pad of the first plurality of bond pads. In one aspect, the first plurality of bond pads and the test structure comprise at least one of aluminum or copper as a principal component, and the first pad metallizations comprise nickel as a principal component. The test structure can comprise a scribe grid pad and the passivation layer can overlie the scribe grid pad.

In this document, reference to a structure comprising “X” does not exclude the structure from comprising a material other than “X” as a principal component, except when specified otherwise, and except when indicated from the context. Further, relational terms such as “first,” “second,” and the like, may be used solely to distinguish one entity or action from another entity or action without necessarily requiring or implying any actual relationship or order between such entities or actions or any actual relationship or order between such entities and claimed elements. The terms “including”, “having”, or any variation thereof, as used herein, are defined as comprising.

Other embodiments, uses, and advantages of the disclosure will be apparent to those skilled in the art from consideration of the specification and practice of the disclosure disclosed herein. The specification and drawings should be considered as examples only, and the scope of the disclosure is accordingly intended to be limited only by the following claims and equivalents thereof.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed.

Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

1. A method comprising:
probing circuitry of a test structure of a wafer having a first die area and a scribe street at a surface of the wafer, the first die area comprising die circuitry and a plurality of bond pads, and the scribe street comprising the test structure;
forming a passivation layer overlying the surface of the wafer after probing the circuitry, the passivation layer overlying the plurality of bond pads and overlying the test structure; and
forming openings in regions of the passivation layer overlying the plurality of bond pads to expose the plurality of bond pads while retaining regions of the passivation layer overlying the test structure until singulation of the wafer.

2. The method of claim 1, further comprising:
forming pad metallizations at the plurality of bond pads via the openings in the regions of the passivation layer prior to singulation of the wafer without forming a pad metallization at the test structure.

3. The method of claim 2, further comprising:
singulating the wafer into a plurality of dies.

4. An integrated circuit (IC) package implementing at least one die fabricated in accordance with the method of claim 3.

5. An electronic device comprising the IC package of claim 4.

6. The method of claim 3, wherein singulating the wafer comprises singulating the wafer using a mechanical saw process.

7. The method of claim 2, wherein forming the pad metallizations comprises metalizing the plurality of bond pads using a maskless over pad metallization (OPM) process.

8. The method of claim 7, wherein aluminum or copper is a principal component of the plurality of bond pads, nickel is a principal component of the pad metallizations, and the maskless OPM process comprises an electroless nickel plating process.

9. The method of claim 1, wherein the test structure comprises a scribe grid pad located in the scribe street, and wherein probing the circuitry comprises contacting the scribe grid pad with a metal probe tip.

10. The method of claim 9, wherein the passivation layer overlies and contacts the scribe grid pad.

11. The method of claim 1, wherein the test structure comprises a conductive interconnect structure located in the scribe street, and wherein probing the circuitry comprises contacting the conductive interconnect structure with a metal probe tip.

12. A method comprising:
forming a passivation layer overlying a surface of a wafer having a plurality of die areas separated by a scribe grid at the surface of the wafer, each die area comprising die circuitry and a plurality of bond pads, and the scribe grid comprising a plurality of scribe grid pads, each scribe grid pad electrically coupled to corresponding test structure circuitry, the passivation layer overlying the bond pads of the plurality of die areas and overlying the plurality of scribe grid pads;
forming passivation openings in regions of the passivation layer that overly the plurality of die areas to expose the bond pads of the plurality of die areas while retaining regions of the passivation layer overlying the scribe grid pads; and
metalizing the bond pads via the passivation openings without metalizing the scribe grid pads.

13. The method of claim 12, further comprising:
singulating the plurality of die areas via the scribe grid.

14. An integrated circuit (IC) package implementing at least one die fabricated in accordance with the method of claim 13.

15. An electronic device comprising the IC package of claim 14.

16. The method of claim 13, wherein singulating the plurality of die areas comprises traversing the scribe grid with a mechanical saw.

17. The method of claim 12, wherein metalizing the bond pads comprises forming a pad metallization in each of the passivation openings using a maskless over pad metallization (OPM) process.

18. A semiconductor wafer comprising:
a first die area comprising a first plurality of bond pads, the first plurality of bond pads coupled to die circuitry of the first die area;
a scribe street adjacent to the first die area, the scribe street comprising a test structure;
a passivation layer overlying the first die area and the scribe street, the passivation layer overlying the test structure; and
first pad metallizations in openings in the passivation layer overlying the first plurality of bond pads, each first pad metallization contacting at least a portion of a corresponding bond pad of the first plurality of bond pads.

19. The semiconductor wafer of claim 18, wherein:
the first plurality of bond pads and the test structure comprise at least one of aluminum or copper as a principal component; and
the first pad metallizations comprise nickel as a principal component.

20. The semiconductor wafer of claim 18, wherein the test structure comprises a scribe grid pad and wherein the passivation layer overlies the scribe grid pad.
